(19) United States
(12) Patent Application Publication
(10) Pub. No.: US 2006/0176111 A1
(43) Pub. Date: Aug. 10, 2006

(54) Electronic device comprising audio mute control circuit

(75) Inventor: Yusuke Takei, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/346,268

(22) Filed: Feb. 3, 2006

(30) Foreign Application Priority Data
Feb. 10, 2005 (JP) 2005-034576

(51) Int. Cl. H03F 1/14

(52) U.S. Cl. 330/51

(57) ABSTRACT

To provide an electronic device comprising an audio mute control circuit for preventing the occurrence of a “click noise” even in “power supply shutdown” not caused by the input of a power switch. An audio mute control circuit 70 is provided which outputs a mute signal to an audio processing circuit 80 based on an audio mute control signal from a microcomputer 30 and a power fail signal from a power failure detection circuit 20 for detecting the presence or absence of power supply from an external power supply, so that when the power fail signal from the power failure detection circuit 20 indicates “no power supply,” the audio processing circuit 80 is muted regardless of the operation of the microcomputer 30. Thus, it is possible to prevent the occurrence of a “click noise” from speakers 90 in “power supply shutdown” not caused by the input of a power switch.

The present application is based on and claims priority of Japanese patent application No. 2005-034576 filed on Feb. 10, 2005, the entire contents of which are hereby incorporated by reference.

### BACKGROUND OF THE INVENTION

1. Field of the Invention

The present invention relates to an electronic device comprising an audio processing circuit for processing an audio signal and particularly relates to an electronic device comprising an audio mute control circuit for preventing the output of a signal acting as noise (click noise) from an audio processing circuit.

2. Description of the Related Art

Conventionally, when the power switch of a device is turned on/off in an electronic device having an audio output function, audio output is muted to prevent the output of a “click noise” which is caused by noise generated in transition to and from start-up or shutdown of a power supply. Conventional techniques for preventing such a “click noise” are disclosed in Japanese Patent Laid-Open Publication No. 9-102751, Japanese Patent Laid-Open Publication No. 2001-267943 and Japanese Patent Laid-Open Publication No. 2003-204591 (Patent Documents 1 to 3) and so on.

“Power supply shutdown” in which the power supply of an electronic device is shifted from an on state to an off state is generally caused by the input of a power switch provided on the device (a main power switch provided on a device or a power switch provided on a remote control). “Power supply shutdown” may occur without the input of a power switch, for example, when a device is unplugged. In recent years, in order to save “standby power consumption” of electronic devices, “power strips” with switches for turning on/off supply of power have been widely used. When the switch of a power strip is turned off in a state in which the power supply of an electronic device is turned on, the electronic device has the same state as the unplugged device. The probability of the occurrence of such a case (“power supply shutdown” not caused by the input of a power switch) has been increased.

The conventional techniques disclosed in the patent documents are devised to prevent a “click sound” from being outputted when the power switch of a device is turned on/off. A state of the power switch of a device is monitored and decided by a microcomputer or the like and audio output is muted according to the state of the power switch. Thus, audio output may not be muted in the case of “power supply shutdown” not caused by the input of the power switch (when power supply from an external power supply is suspended), or a “click noise” may occur when muting is late (power shutdown noise occurs before a mute signal is outputted through processing in a microcomputer or the like).

### SUMMARY OF THE INVENTION

In view of the above-described points, the present invention has as its object the provision of an electronic device comprising an audio mute control circuit for preventing the occurrence of a “click sound” even in “power supply shutdown” not caused by the input of a power switch.

An electronic device comprises an audio mute control circuit according to claim 1, the electronic device further comprising: a power supply unit for receiving power supply from an external power supply and supplying the power to the overall device, a power failure detection circuit for detecting presence or absence of power supply from the external power supply to the power supply unit and outputting a detection result as a power fail signal, and an audio processing circuit for processing an audio signal, characterized in that the power fail signal outputted from the power failure detection circuit is used as a mute control signal of the audio processing circuit.

With this configuration, the power fail signal outputted from the power failure detection circuit capable of detecting the suspension of power supply from the external power supply (“power supply shutdown” not caused by the input of a power switch) is used as the mute control signal of the audio processing circuit.

An electronic device comprising an audio mute control circuit according to claim 2 is an electronic device comprising the audio mute control circuit of claim 1, characterized in that the audio mute control circuit is a switching circuit performing a switching operation in response to a mute control signal from a microcomputer and a power fail signal outputted from the power failure detection circuit, the audio mute control circuit outputs a mute command to the audio processing circuit when the power fail signal indicates the absence of power supply from the external power supply to the power supply unit, and the audio mute control circuit outputs a mute control signal to the audio processing circuit according to the state of the mute control signal from the microcomputer when the power fail signal indicates the presence of power supply from the external power supply to the power supply unit.

With this configuration, when the power failure detection circuit detects the suspension of power supply from the external power supply, the audio processing circuit is muted by the power fail signal outputted from the power failure detection circuit. In the presence of power supply, the muting operation of the audio processing circuit is controlled by the mute control signal from the microcomputer.

An electronic device comprising an audio mute control circuit according to claim 3 is an electronic device comprising the audio mute control circuit of claim 2, characterized in that the audio mute control circuit is configured such that a power fail output terminal provided on the power failure detection circuit to output the power fail signal is connected to the base of a first transistor, a constant voltage source is connected to the collector of the first transistor, a collector of a second transistor is connected to an emitter of the first transistor, a mute control signal output terminal provided on the microcomputer to output the mute control signal is connected to a base of the second transistor, an emitter of the second transistor is connected to the ground, the collector of the second transistor and a base of a third transistor are connected to each other, a collector of the third transistor is connected to the constant voltage source, and an emitter of the third transistor is connected to the ground, and the mute control signal is outputted from the collector of the third transistor to the audio processing circuit.

With this configuration, when the power failure detection circuit detects the suspension of power supply from the external power supply, the first transistor is turned off in response to the power fail signal outputted from the power failure detection circuit, so that the third transistor is also turned off. Thus, the output of the constant voltage source is directly inputted to the audio mute control circuit and acts as a mute command. Therefore, the control of the microcomputer or the like or an element controlled by the microcomputer or the like is not present between “the detection of the suspension of power supply from the external power supply” and “the output of the mute command to the audio mute control circuit.”

An electronic device comprising an audio mute control circuit according to claim 4 is an electronic device comprising the audio mute control circuit of claim 2, characterized in that the audio mute control circuit is configured such that a power fail output terminal provided on the power failure detection circuit to output the power fail signal is connected to a base of a fourth transistor, a constant voltage source is connected to a collector of the fourth transistor, an emitter of the fourth transistor is connected to ground, a collector of a fifth transistor having a base connected to a mute control signal output terminal and the base of the fourth transistor are connected to each other, the mute control signal output terminal being provided on the microcomputer to output the mute control signal, and the emitter of the fifth transistor is connected to the ground, and the mute control signal is outputted from the collector of the fourth transistor to the audio processing circuit.

With this configuration, the “audio mute control circuit” can be configured with two transistors.

### BRIEF DESCRIPTION OF THE DRAWINGS

FIG. 1 is a block diagram schematically showing only a part of a liquid crystal display according to the present invention.

FIG. 2 is a perspective view showing the liquid crystal display.

FIG. 3 is a circuit diagram showing an example of an audio mute control circuit.

FIG. 4 is a circuit diagram schematically showing an audio mute control circuit of Embodiment 2.

FIG. 5 is a block diagram showing an example of a conventional device.

### DETAILED DESCRIPTION OF THE PREFERRED EMBODIMENTS

Specific embodiments of the present invention will be described below in accordance with the accompanying drawings. The following embodiments are just concrete forms of the present invention and thus the present invention is not limited within the embodiments.

### EMBODIMENT 1

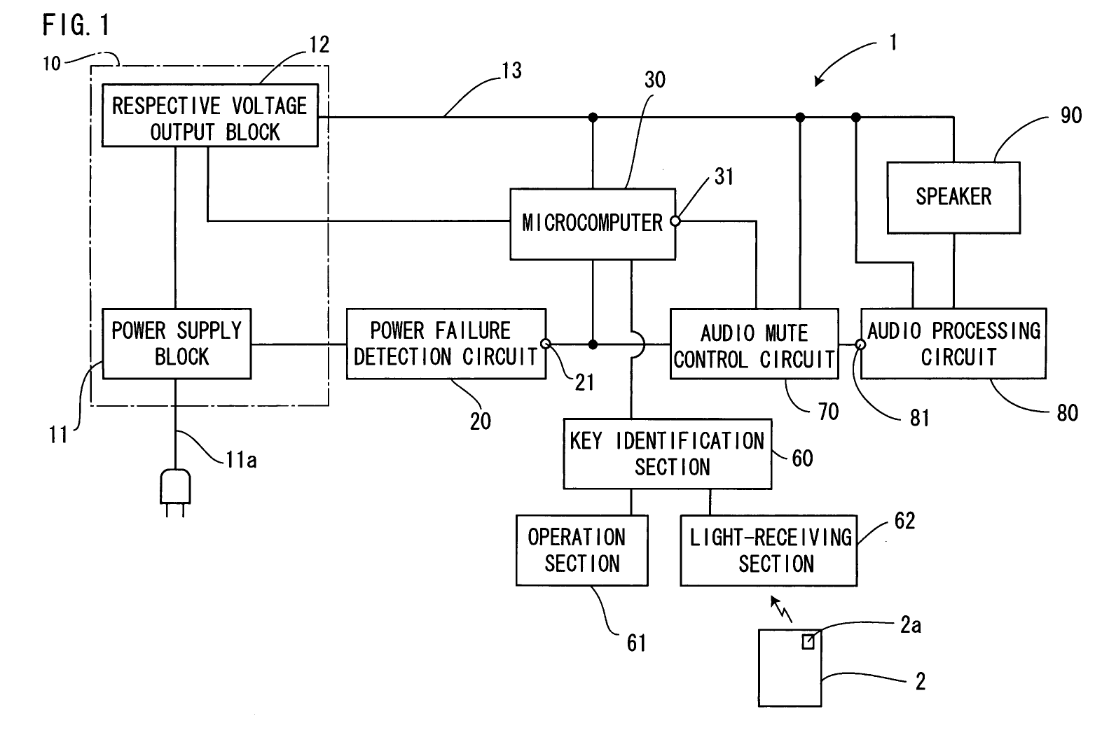

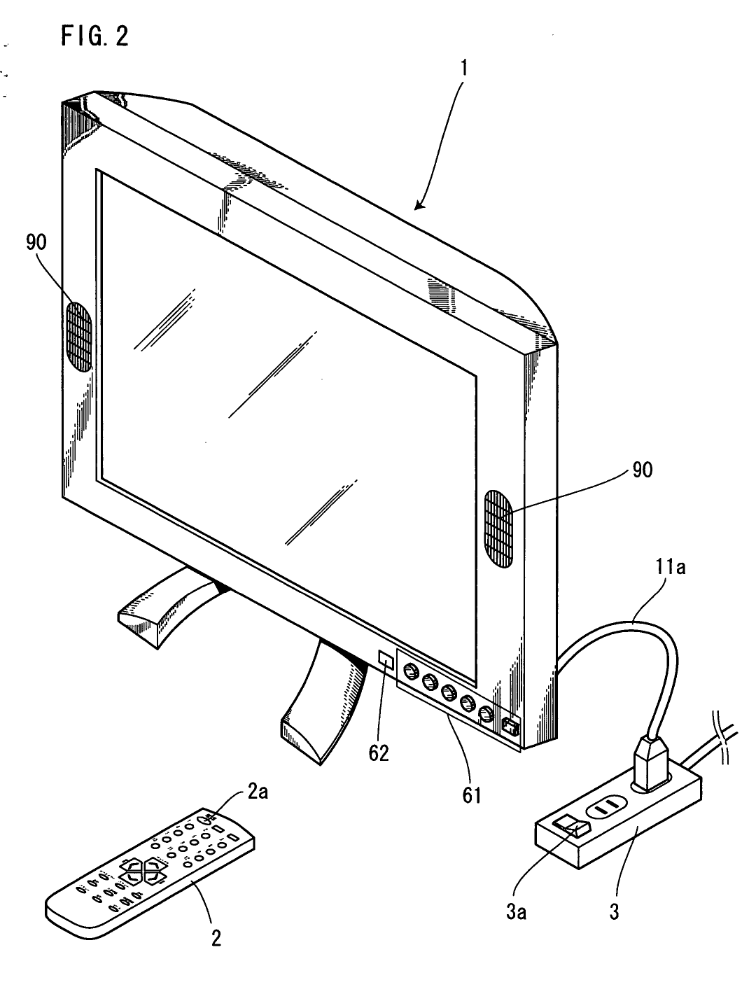

FIG. 1 is a block diagram schematically showing only a part of a liquid crystal display of the present embodiment according to the present invention. FIG. 2 is a perspective view showing the liquid crystal display.

As shown in FIG. 1, a liquid crystal display (hereinafter, simply referred to as an LCD) 1 of the present embodiment comprises a power supply unit 10 which is fed with power from a commercial power supply (external power supply) through a power cord 11a and supplies the power to the overall device, a power failure detection circuit 20 which detects the presence or absence of power supply from the commercial power supply to the power supply unit 10 and outputs the detection result as a power fail signal, a microcomputer 30 for controlling the overall device, a key identification section 60 which identifies a signal from an operation section 61 or a light-receiving section 62 and outputs the signal, an audio mute control circuit 70 which performs a switching operation in response to a mute control signal from the microcomputer 30 and the power fail signal outputted from the power failure detection circuit 20, an audio processing circuit 80 for processing an audio signal, and a speaker 90 which outputs audio in response to a signal from the audio processing circuit 80.

A respective voltage output block 12 provided in the power supply unit 10 supplies corresponding voltages to the respective parts of the device (so-called secondary power supply in FIG. 2 which shows, for simplicity, that power is fed to each part through a single power supply line 13, though power supply lines are provided for the respective voltages in an actual configuration) and the on/off of power supply is controlled by the microcomputer 30 (for example, power supply to an unnecessary part is shut off during standby). The power failure detection circuit 20 detects the presence or absence of power supply from the commercial power supply to the power supply unit 10. In the present embodiment, the power failure detection circuit 20 outputs, as a power fail signal, a high-level signal (DC voltage) in the presence of power supply from the commercial power supply, and outputs a low-level signal when power supply from the commercial power supply is suspended (for example, when power fails, the power cord 11a is removed, or a switch 3a of a power strip 3 (FIG. 2) connected to the power cord 11a is turned off). The audio mute control circuit 70 outputs a mute control signal for controlling the muting operation of the audio processing circuit 80, based on a mute control signal from the microcomputer 30 and the power fail signal outputted from the power failure detection circuit 20.

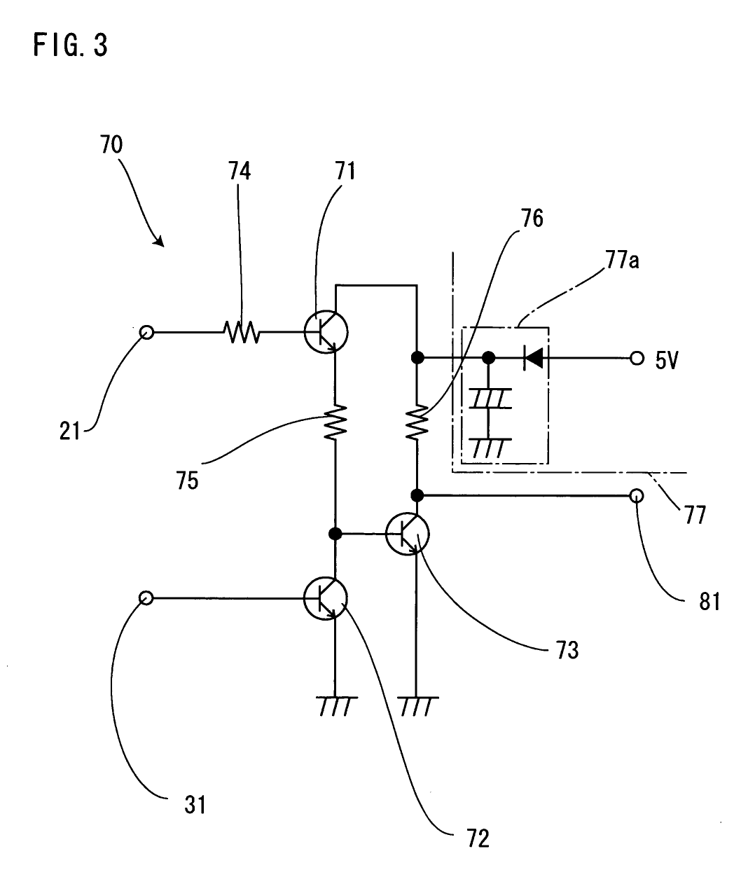

FIG. 3 shows an example of the circuit configuration of the audio mute control circuit 70. As shown in FIG. 3, the audio mute control circuit 70 is configured such that the base of a transistor 71 (first transistor) is connected to a power fail output terminal 21 via a resistor 74, the power fail output terminal 21 being provided on the power failure detection circuit 20 to output the power fail signal, a constant voltage source 77 is connected to the collector of the transistor 71 (the constant voltage source 77 is connected to a 5V power supply line via a rectifying/smoothing circuit 77a, and mainly acts, in the operation of the present invention, as a backup power supply in the absence of power supply from the external power supply, though referred to as a “constant voltage source,” and the constant voltage source 77 inputs, after power supply is suspended, a “mute control signal” to a mute control input terminal 81 in response to discharge of charge built up on a capacitor provided in the rectifying/smoothing circuit 77a), the collector of a transistor 72 (second transistor) is connected to the emitter of the transistor 71 via a resistor 75, a mute control signal output terminal 31 is connected to the base of the transistor 72, the terminal 31 being provided on the microcomputer 30 to output the mute control signal, the emitter of the transistor 72 is connected to the ground, the collector of the transistor 72 and the base of a transistor 73 (third transistor) are connected to each other, the constant voltage source 77 is connected to the collector of the transistor 73 via a resistor 76, the emitter of the transistor 73 is connected to the ground, and the collector of the transistor 73 is connected to the mute control signal input terminal 81 which is provided on the audio processing circuit 80 and receives the input of the mute control signal.

The following is the outline of the operation of the audio mute control circuit 70 configured thus. When the power fail signal from the power fail output terminal 21 is at high-level (in other words, in the presence of power supply from the commercial power supply), the transistor 71 is turned on. Thus, the on/off of the transistor 73 is controlled by the mute control signal from the microcomputer 30. That is, when the mute control signal from the microcomputer 30 (mute control signal output terminal 31) is a high-level signal, since the transistor 72 is turned on, the base of the transistor 73 has a ground potential (precisely, higher than the ground potential by a voltage drop of the transistor 72) and the transistor 73 is turned off. On the other hand, when the mute control signal from the microcomputer 30 is a low-level signal, the transistor 72 is turned off and the voltage of the constant voltage source 77 is applied to the base of the transistor 73 after being adjusted by the resistor 75, so that the transistor 73 is turned on. In response to the on/off of the transistor 73, the voltage (high-level signal) of the constant voltage source 77 is inputted to the mute control signal input terminal 81 after being adjusted by the ground potential (low-level signal)/resistor 76. Thus, when the power fail signal is at high level, the muting operation of the audio processing circuit 80 is controlled by the mute control signal from the microcomputer 30.

In contrast, when the power fail signal from the power fail output terminal 21 is at low level (in other words, in the absence of power supply from the commercial power supply), the transistor 71 is turned off and the transistor 73 is also turned off accordingly. Thus, the voltage (high-level signal) of the constant voltage source 77 is inputted to the mute control signal input terminal 81 after being adjusted by the resistor 76. Therefore, when the power fail signal is at low level, regardless of the mute control signal from the microcomputer 30, the audio processing circuit 80 is immediately muted by the power fail signal from the power failure detection circuit 20.

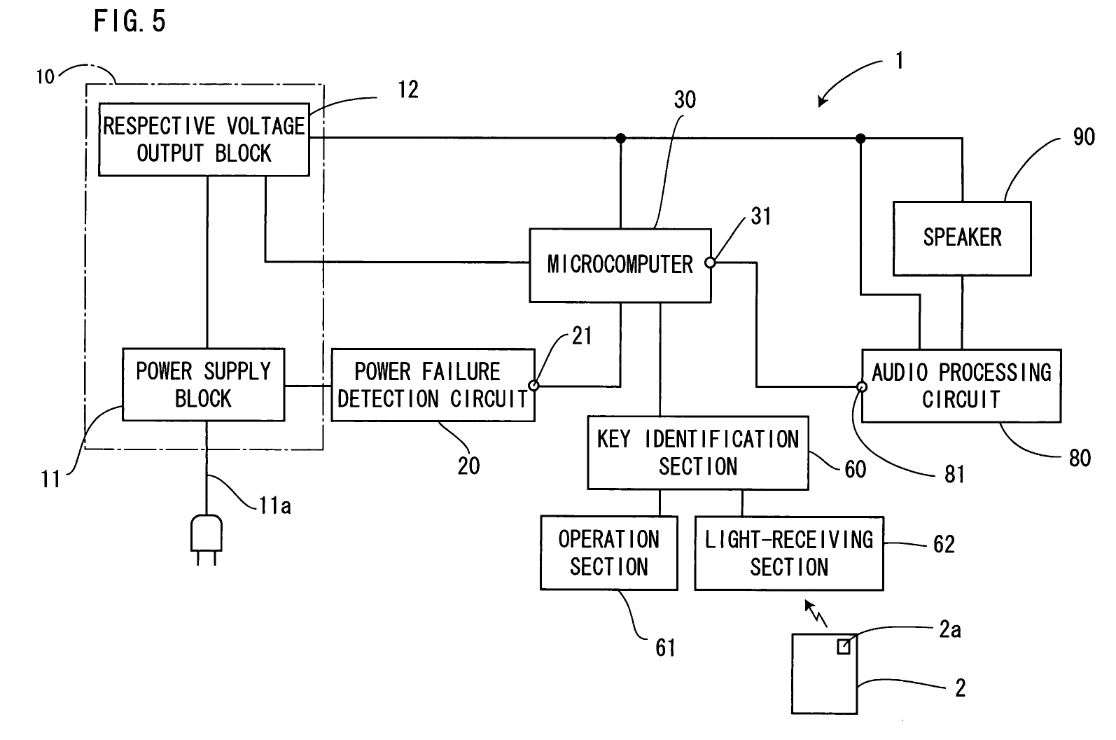

FIG. 5 is a block diagram schematically showing an example of a conventional device (the same constituent elements as the present embodiment are indicated by the same reference numerals). In this device, for example, when the device is powered off by the input of a power switch 2a provided on a remote control unit 2, a microcomputer 30 obtains a “power-off command” through a key identification section 60, outputs a mute command to an audio processing circuit 80, and then “stops power supply” to a respective voltage output block 12. Thus, muting can be performed in the audio processing circuit 80 before “power supply shutdown,” thereby preventing the occurrence of a “click noise.” However, when power supply from an external power supply is suspended, for example, due to the removal of a power cord 11a, decision and processing are performed in the microcomputer 30 in response to a signal from a power failure detection circuit 20 having detected the suspension of power supply, and a mute signal is outputted to the audio processing circuit 80. In the audio processing circuit 80, immediately after “power supply from the external power supply is suspended,” “power supply shutdown” may occur (the timing of “power supply shutdown” varies with the designs of a power supply unit, and when a large-capacity capacitor or the like is provided on a power supply line to delay the timing of “power supply shutdown,” the cost and the circuit space are increased). Thus, due to delay caused by processing time or the like in the microcomputer 30, muting is late and a “click noise” may occur from speakers 90. When the power failure detection circuit 20 is not provided and the voltage of a power supply output line (secondary power supply line) from the respective voltage output block 12 is monitored by the microcomputer 30, response is further delayed (a power supply line generally comprises a capacitor and the detection of “power supply suspension” is delayed by a time to discharge charge built up on the capacitor), so that muting is late and a “click noise” may occur from the speakers 90.

According to the present embodiment in contrast to the conventional device, as described above, the suspension of power supply from the external power supply is instantly detected by the power failure detection circuit and a mute command is outputted to the audio processing circuit 80 without passing through the processing of the microcomputer 30 or an element controlled by the microcomputer 30. Thus, it is possible to achieve a quick response and effectively prevent the occurrence of a “click noise.”

### EMBODIMENT 2

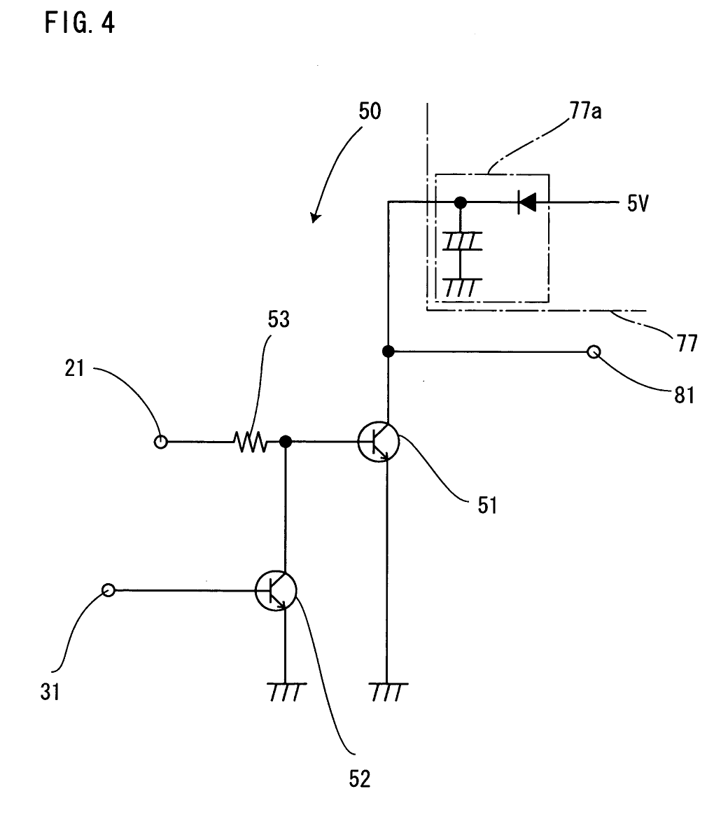

FIG. 4 is a circuit diagram schematically showing an audio mute control circuit of the present embodiment. A device comprising the audio mute control circuit is an LCD similar to that of Embodiment 1. The same constituent elements as Embodiment 1 are indicated by the same reference numerals and the explanation thereof is omitted.

As shown in FIG. 4, an audio mute control circuit 50 is configured such that the base of a transistor 51 (fourth transistor) is connected to a power fail output terminal 21 via a resistor 53, the power fail output terminal 21 being provided on a power failure detection circuit 20 to output a power fail signal, a constant voltage source 77 is connected to the collector of the transistor 51, the emitter of the transistor 51 is connected to the ground, the collector of a transistor 52 (fifth transistor) having its base connected to a mute control signal output terminal 31 is connected to the base of the transistor 51, the emitter of the transistor 52 is connected to the ground, and the collector of the transistor 51 is connected to a mute control signal input terminal 81.

The following is the outline of the operation of the audio mute control circuit 50 configured thus. When the power fail signal from the power fail output terminal 21 is at high level, the on/off of the transistor 51 is controlled by a mute control signal from a microcomputer 30 (the mute control signal output terminal 31). That is, when the mute control signal from the microcomputer 30 is a high-level signal, since the transistor 52 is turned on, the base of the transistor 51 has a ground potential and the transistor 51 is turned off. On the other hand, when the mute control signal from the microcomputer 30 is a low-level signal, the transistor 52 is turned off and a power fail signal (high level) is inputted to the base of the transistor 51, so that the transistor 51 is turned on. In response to the on/off of the transistor 51, the ground potential (low-level signal)/the voltage (high-level signal) of a constant voltage source 77 are inputted to the mute control signal input terminal 81. Thus, when the power fail signal is at high level, the muting operation of an audio processing circuit 80 is controlled by the mute control signal from the microcomputer 30.

In contrast, when the power fail signal from the power fail output terminal 21 is at low level, the transistor 51 is turned off. Thus, the voltage (high-level signal) of the constant voltage source 77 is inputted to the mute control signal input terminal 81. Therefore, when the power fail signal is at low level, regardless of the mute control signal from the microcomputer 30, the audio processing circuit 80 is muted by the power fail signal from the power failure detection circuit 20.

As described above, according to the audio mute control circuit 50 of the present embodiment, the same operation as the audio mute control circuit 70 of Embodiment 1 is performed, thereby effectively preventing the occurrence of a “click noise.” Additionally, the audio mute control circuit can be configured with two transistors, achieving an inexpensive and space-saving circuit configuration. Further, during an operation when the power fail signal is at low level, a control signal is inputted from the power failure detection circuit 20 to the audio processing circuit 80 only through a single transistor, thereby effectively preventing the occurrence of a “click noise” with higher responsiveness.

Resistors in the audio mute control circuit of the embodiment are mainly used for fine adjustments on voltage and the resistors are not always necessary for some qualities of voltage applied to each signal line (the design of each circuit connected to the audio mute control circuit). In these embodiments, an LCD was described as a specific example of an electronic device. The present invention is not limited to this example and is applicable to an electronic device comprising a power failure detection circuit and an audio processing circuit. Moreover, the present invention can be effectively applied to an electronic device comprising no speakers (for example, a recording/reproducing device such as a DVD player) as long as the electronic device comprises an audio processing circuit.

The electronic device comprises the audio mute control circuit according to claim 1, the electronic device further comprising: the power supply unit for receiving power supply from the external power supply and supplying the power to the overall device, the power failure detection circuit for detecting the presence or absence of power supply from the external power supply to the power supply unit and outputting a detection result as a power fail signal, and the audio processing circuit for processing the audio signal, characterized in that the power fail signal outputted from the power failure detection circuit is used as the mute control signal of the audio processing circuit. With this configuration, the power fail signal outputted from the power failure detection circuit capable of detecting the suspension of power supply from the external power supply (“power supply shutdown” not caused by the input of a power switch) is used as the mute control signal of the audio processing circuit. Thus, it is possible to effectively prevent the occurrence of a “click noise” even in “power supply shutdown” not caused by the input of a power switch (for example, when the AC plug of the device is removed or power supply is suspended by turning off the switch of a power strip).

The electronic device comprises the audio mute control circuit of claim 2 according to claim 3 of the present invention, characterized in that the audio mute control circuit is configured such that the power fail output terminal provided on the power failure detection circuit to output the power fail signal is connected to the base of the first transistor, the constant voltage source is connected to the collector of the first transistor, the collector of the second transistor is connected to the emitter of the first transistor, the mute control signal output terminal provided on the microcomputer to output the mute control signal is connected to the base of the second transistor, the emitter of the second transistor is connected to the ground, the collector of the second transistor and the base of the third transistor are connected to each other, the collector of the third transistor is connected to the constant voltage source, and the emitter of the third transistor is connected to the ground, and the mute control signal is outputted from the collector of the third transistor to the audio processing circuit. With this configuration, the control of the microcomputer or the like or an element controlled by the microcomputer or the like is not present between “the detection of the suspension of power supply from the external power supply” and “the output of the mute command to the audio mute control circuit.” Thus, it is possible to effectively prevent the occurrence of a “click noise” with high responsiveness (because there is no processing time in the microcomputer).

The electronic device comprises the audio mute control circuit of claim 2 according to claim 4, characterized in that the audio mute control circuit is configured such that the power fail output terminal provided on the power failure detection circuit to output the power fail signal is connected to the base of the fourth transistor, the constant voltage source is connected to the collector of the fourth transistor, the emitter of the fourth transistor is connected to the ground, the collector of the fifth transistor having a base connected to the mute control signal output terminal and the base of the fourth transistor are connected to each other, the mute control signal output terminal being provided on the microcomputer to output the mute control signal, and the emitter of the fifth transistor is connected to the ground, and the mute control signal is outputted from the collector of the fourth transistor to the audio processing circuit. With this configuration, the “audio mute control circuit” can be configured with two transistors. Therefore, it is possible to reduce the space of the circuit and the cost of the device and increase responsiveness because of a smaller number of circuit elements, thereby effectively preventing the occurrence of a “click noise.”

What is claimed is:

1. An electronic device comprising an audio mute control circuit, the electronic device further comprising: a power supply unit for receiving power supply from an external power supply and supplying the power to the overall device, a power failure detection circuit for detecting presence or absence of power supply from the external power supply to the power supply unit and outputting a detection result as a power fail signal, and an audio processing circuit for processing an audio signal, characterized in that the power fail signal outputted from the power failure detection circuit is used as a mute control signal of the audio processing circuit.

2. An electronic device comprising the audio mute control circuit of claim 1, characterized in that the audio mute control circuit is a switching circuit performing a switching operation in response to a mute control signal from a microcomputer and a power fail signal outputted from the power failure detection circuit, the audio mute control circuit outputs a mute command to the audio processing circuit when the power fail signal indicates the absence of power supply from the external power supply to the power supply unit, and the audio mute control circuit outputs a mute control signal to the audio processing circuit according to the state of the mute control signal from the microcomputer when the power fail signal indicates the presence of power supply from the external power supply to the power supply unit.

3. An electronic device comprising the audio mute control circuit of claim 2, characterized in that the audio mute control circuit is configured such that a power fail output terminal provided on the power failure detection circuit to output the power fail signal is connected to a base of a first transistor, a constant voltage source is connected to a collector of the first transistor, a collector of a second transistor is connected to an emitter of the first transistor, a mute control signal output terminal provided on the microcomputer to output the mute control signal is connected to a base of the second transistor, an emitter of the second transistor is connected to the ground, the collector of the second transistor and a base of a third transistor are connected to each other, a collector of the third transistor is connected to the constant voltage source, and an emitter of the third transistor is connected to the ground, and the mute control signal is outputted from the collector of the third transistor to the audio processing circuit.

4. An electronic device comprising the audio mute control circuit of claim 2, characterized in that the audio mute control circuit is configured such that a power fail output terminal provided on the power failure detection circuit to output the power fail signal is connected to a base of a fourth transistor, a constant voltage source is connected to a collector of the fourth transistor, an emitter of the fourth transistor is connected to the ground, a collector of a fifth transistor having a base connected to a mute control signal output terminal and the base of the fourth transistor are connected to each other, the mute control signal output terminal being provided on the microcomputer to output the mute control signal, and an emitter of the fifth transistor is connected to the ground, and the mute control signal is outputted from the collector of the fourth transistor to the audio processing circuit.
